(19) United States
(12) Patent Application Publication
(10) Pub. No.: US 2025/0385035 A1
(43) Pub. Date: Dec. 18, 2025

(54) Integrated transformer and balanced-to-unbalanced transformer

(71) Applicant: REALTEK SEMICONDUCTOR CORPORATION, Hsinchu (TW)

(72) Inventor: CHENG-WEI LUO, Hsinchu (TW)

(21) Appl. No.: 19/231,188

(22) Filed: Jun. 6, 2025

(30) Foreign Application Priority Data
Jun. 12, 2024 (TW) 113121690

(51) Int. Cl. H01F 27/28; H01F 19/00; H03H 7/42

(52) U.S. Cl. CPC H01F 27/2804; H01F 19/00; H03H 7/42

(57) ABSTRACT

An integrated transformer, substantially symmetrical about an axis of symmetry, having first to fourth terminals and including primary and secondary coils and first and second crossing structures. The primary coil, whose two terminals are the first and second terminals, includes a first trace. The secondary coil, whose two terminals are the third and fourth terminals, includes a second trace and a third trace. The first crossing structure is formed by the second trace and a first portion of the first trace. The second crossing structure is formed by the third trace and a second portion of the first trace. The first and second terminals are on two sides of the axis of symmetry. The third and fourth terminals are on two sides of the axis of symmetry. The first and second crossing structures are substantially symmetrical about the axis of symmetry.

### BACKGROUND OF THE INVENTION

### 1. Field of the Invention

The present invention generally relates to an integrated transformer and a balanced-to-unbalanced transformer (hereinafter referred to as a balun), and more particularly, to an integrated transformer and a balun where the ratio of the inductance value of the primary coil to the inductance value of the secondary coil is not 1.

### 2. Description of Related Art

Reference is made to FIG. 1, which shows the structure of a conventional transformer. The transformer 100 includes a primary coil and a secondary coil. The terminal 101a and the terminal 101b are two terminals of the primary coil, while the terminal 111a and the terminal 111b are two terminals of the secondary coil. The transformer 100 is a symmetrical structure. More specifically, the primary coil and the secondary coil are both symmetrical with respect to the dashed line at the center, which makes the inductance value of the primary coil and the inductance value of the secondary coil substantially the same. However, the transformer 100 is not applicable to the situation where the inductance value of the primary coil and the inductance value of the secondary coil are not 1:1.

### SUMMARY OF THE INVENTION

In view of the issues of the prior art, an object of the present invention is to provide an integrated transformer and a balun, so as to make an improvement to the prior art.

According to one aspect of the present invention, an integrated transformer is provided. The integrated transformer has a first terminal, a second terminal, a third terminal, and a fourth terminal. The integrated transformer includes: a primary coil including a first trace, wherein the first terminal and the second terminal are two terminals of the primary coil; a secondary coil including a second trace and a third trace, wherein the third terminal and the fourth terminal are two terminals of the secondary coil; a first crossing structure formed by a first portion of the first trace and the second trace; and a second crossing structure formed by a second portion of the first trace and the third trace. The integrated transformer is substantially symmetrical with respect to an axis of symmetry. The first terminal and the second terminal are located on two sides of the axis of symmetry. The third terminal and the fourth terminal are located on two sides of the axis of symmetry. The first crossing structure and the second crossing structure are substantially symmetrical with respect to the axis of symmetry.

According to another aspect of the present invention, a balanced-to-unbalanced transformer (balun) is provided. The balun has a first terminal, a second terminal, a third terminal, a fourth terminal, and a fifth terminal. The balun includes: a primary coil including a first trace, wherein the first terminal and the second terminal are two terminals of the primary coil; a secondary coil including a second trace and a third trace, wherein the third terminal, the fourth terminal, and the fifth terminal are three terminals of the secondary coil; a first crossing structure formed by a first portion of the first trace and the second trace; and a second crossing structure formed by a second portion of the first trace and the third trace. The balun is substantially symmetrical with respect to an axis of symmetry. The first terminal and the second terminal are located on two sides of the axis of symmetry. The third terminal and the fourth terminal are located on two sides of the axis of symmetry. The fifth terminal is located on the axis of symmetry, and the first crossing structure and the second crossing structure are substantially symmetrical with respect to the axis of symmetry.

The technical means embodied in the embodiments of the present invention can solve at least one of the problems of the prior art. Therefore, compared to the prior art, the present invention is easier to implement an integrated transformer and a balun where the ratio of the inductance value of the primary coil to the inductance value of the secondary coil is not 1.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows the structure of a conventional transformer.

FIG. 2 shows the structure of an integrated transformer according to an embodiment of the present invention.

FIGS. 3A and 3B show the primary coil 210 and the secondary coil 220 in FIG. 2.

FIG. 4 shows the structure of an integrated transformer according to another embodiment of the present invention.

FIG. 5 shows the structure of an integrated transformer according to another embodiment of the present invention.

FIG. 6 shows the relationship between the inductance value and the frequency of the integrated transformer according to the present invention.

FIG. 7 shows the structure of a balun according to an embodiment of the present invention.

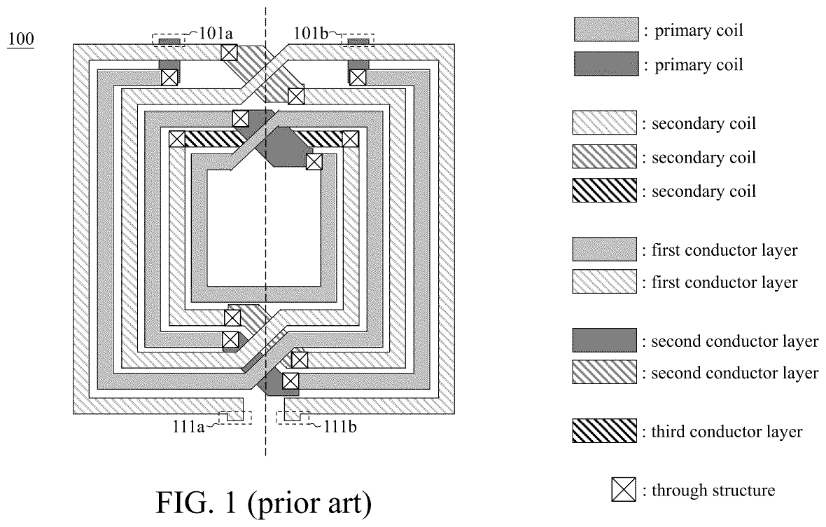

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an integrated transformer and a balun. On account of that some or all elements of the integrated transformer and the balun could be known, the detail of such elements is omitted provided that such detail has little to do with the features of this disclosure, and that this omission nowhere dissatisfies the specification and enablement requirements. A person having ordinary skill in the art can choose components equivalent to those described in this specification to carry out the present invention, which means that the scope of this invention is not limited to the embodiments in the specification.

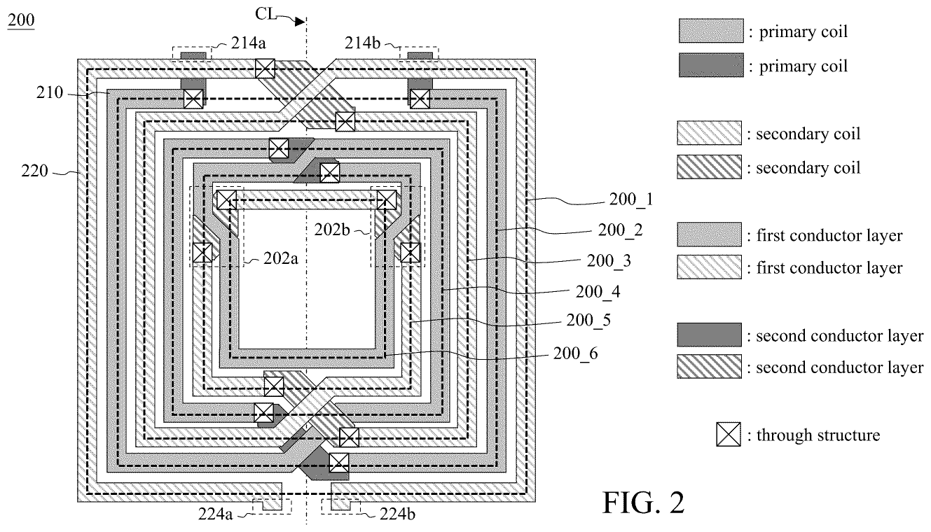

Reference is made to FIG. 2, which shows the structure of the integrated transformer according to an embodiment of the present invention. The integrated transformer 200 includes a primary coil 210 and a secondary coil 220. The terminal 214a and the terminal 214b are two terminal of the primary coil 210. The terminal 224a and the terminal 224b are two terminal of the secondary coil 220. The integrated transformer 200 is substantially symmetrical with respect to the axis of symmetry CL. More specifically, the terminal 214a and the terminal 214b are located on two sides of the axis of symmetry CL and are substantially symmetrical with respect to the axis of symmetry CL, the terminal 224a and the terminal 224b are located on two sides of the axis of symmetry CL and are substantially symmetrical with respect to the axis of symmetry CL, and the crossing structure 202a and the crossing structure 202b are located on two sides of the axis of symmetry CL and are substantially symmetrical with respect to the axis of symmetry CL.

The integrated transformer 200 sequentially includes, from the outer turn to the inner turn, the first turn 200_1, the second turn 200_2, the third turn 200_3, the fourth turn 200_4, the fifth turn 200_5, and the sixth turn 200_6. The first turn 200_1 and the sixth turn 200_6 are respectively the outermost turn and the innermost turn of the integrated transformer 200.

The first turn 200_1, the second turn 200_2, the third turn 200_3, and the fourth turn 200_4 are respectively formed by a portion of the secondary coil 220, a portion of the primary coil 210, a portion of the secondary coil 220, and a portion of the primary coil 210. In other words, the first turn 200_1 and the third turn 200_3 substantially only include the secondary coil 220, while the second turn 200_2 and the fourth turn 200_4 substantially only include the primary coil 210.

The fifth turn 200_5 and the sixth turn 200_6 are each formed by a portion of a primary coil 210 and a portion of a secondary coil 220, and the fifth turn 200_5 and the sixth turn 200_6 are consecutive turns of the integrated transformer 200. In other words, the fifth turn 200_5 substantially includes a portion of the primary coil 210 and a portion of the secondary coil 220, and the sixth turn 200_6 substantially includes a portion of the primary coil 210 and a portion of the secondary coil 220.

The crossing structure 202a and the crossing structure 202b connect the fifth turn 200_5 and the sixth turn 200_6, and each is formed by a portion of a primary coil 210 and a portion of a secondary coil 220.

The integrated transformer 200 is embodied on a first conductor layer and a second conductor layer of a semiconductor structure. In other words, the traces of the primary coil 210 are distributed on the first conductor layer and the second conductor layer, and the traces of the secondary coil 220 are distributed on the first conductor layer and the second conductor layer. The primary coil 210 and the secondary coil 220 are each divided into multiple traces by multiple through structures. The traces located on different layers are connected by a through structure. In some embodiments, the first conductor layer is a re-distribution layer (RDL), and the second conductor layer is an ultra-thick metal (UTM) layer. In other embodiments, the first conductor layer is the UTM layer, and the second conductor layer is the RDL. The through structure may be a through silicon via (TSV). Compared to the transformer 100, because the integrated transformer 200 only requires two conductor layers, it is easier to implement.

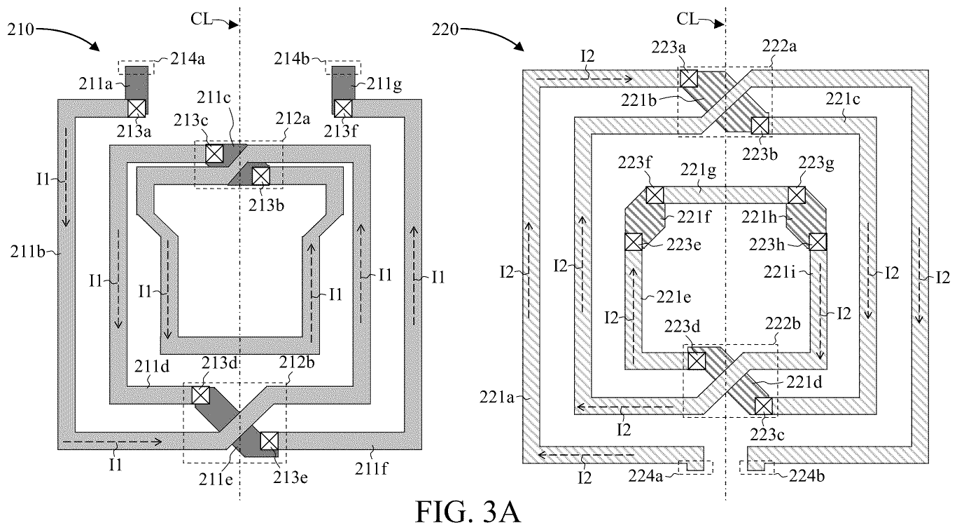

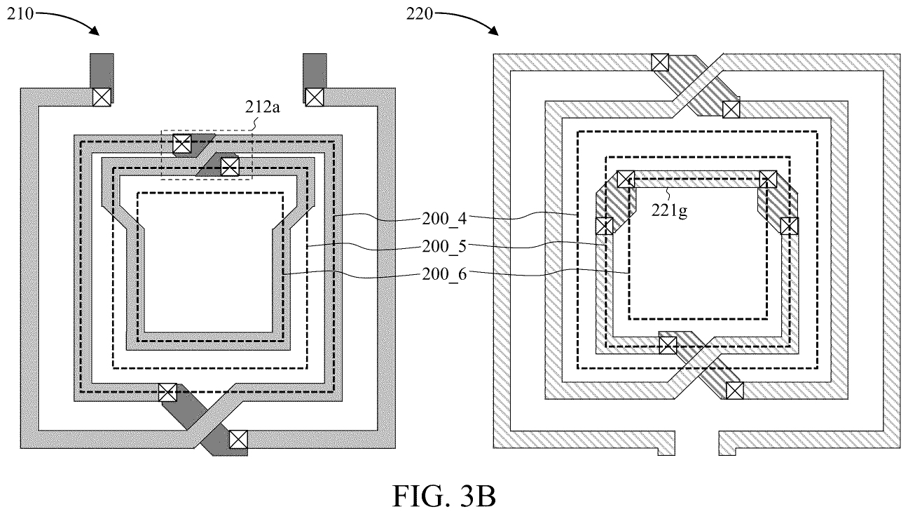

Reference is made to FIG. 3A and FIG. 3B, which show the primary coil 210 and the secondary coil 220 in FIG. 2.

The primary coil 210 includes the traces 211a to 211g, the crossing structures 212a and 212b, and the through structures 213a to 213f. The trace 211a, the trace 211c, the trace 211e, and the trace 211g are implemented on the second conductor layer, while the trace 211b, the trace 211d, and the trace 211f are implemented on the first conductor layer. The trace 211a and the trace 211b are connected through the through structure 213a. The trace 211b and the trace 211c are connected through the through structure 213b. The trace 211c and the trace 211d are connected through the through structure 213c. The trace 211d and the trace 211e are connected through the through structure 213d. The trace 211e and the trace 211f are connected through the through structure 213e. The trace 211f and the trace 211g are connected through the through structure 213f.

The crossing structure 212a is formed by the trace 211c and a portion of the trace 211b, and connects the fourth turn 200_4 and the fifth turn 200_5 of the integrated transformer 200. The crossing structure 212b is formed by the trace 211e and a portion of the trace 211b, and connects the second turn 200_2 and the fourth turn 200_4 of the integrated transformer 200. The crossing structure 212a and the crossing structure 212b are on the axis of symmetry CL.

The current entering the primary coil 210 from the terminal 214a flows in a counterclockwise direction (the direction of the current I1) through all the traces and then exits the primary coil 210 from the terminal 214b.

The secondary coil 220 includes the traces 221a to 221i, the crossing structures 222a to 222b, and the through structures 223a to 223h. The trace 221a, the trace 221c, the trace 221e, the trace 221g, and the trace 221i are implemented on the first conductor layer, while the trace 221b, the trace 221d, the trace 221f, and the trace 221h are implemented on the second conductor layer. The trace 221a and the trace 221b are connected through the through structure 223a. The trace 221b and the trace 221c are connected through the through structure 223b. The trace 221c and the trace 221d are connected through the through structure 223c. The trace 221d and the trace 221e are connected through the through structure 223d. The trace 221e and the trace 221f are connected through the through structure 223e. The trace 221f and the trace 221g are connected through the through structure 223f. The trace 221g and the trace 221h are connected through the through structure 223g. The trace 221h and the trace 221i are connected through the through structure 223h.

The crossing structure 222a is formed by the trace 221b and a portion of the trace 221i, and connects the first turn 200_1 and the third turn 200_3 of the integrated transformer 200. The crossing structure 222b is formed by the trace 221d and a portion of the trace 221i, and connects the third turn 200_3 and the fifth turn 200_5 of the integrated transformer 200. The crossing structure 222a and the crossing structure 222b are on the axis of symmetry CL.

The current entering the secondary coil 220 from the terminal 224a flows in a clockwise direction (the direction of the current I2) through all the traces and then exits the secondary coil 220 from the terminal 224b.

Reference is made to FIG. 2 and FIG. 3A. The crossing structure 202a is formed by a portion of the primary coil 210 (more specifically, a portion of the trace 211b) and a portion of the secondary coil 220 (more specifically, the trace 221f). The crossing structure 202b is formed by a portion of the primary coil 210 (more specifically, a portion of the trace 211b) and a portion of the secondary coil 220 (more specifically, the trace 221h). The crossing structure 202a and the crossing structure 202b are located at the innermost turn of the primary coil 210 and the innermost turn of the secondary coil 220.

The crossing structure 212a of the primary coil 210 does not cross any trace of the secondary coil 220. The crossing structure 212b of the primary coil 210 crosses a portion of the trace of the secondary coil 220 (more specifically, crosses a portion of the crossing structure 222b). The crossing structure 222b of the secondary coil 220 crosses a portion of the trace of the primary coil 210 (more specifically, crosses a portion of the crossing structure 212b). Although the crossing structure 222a of the secondary coil 220 does not cross any trace of the primary coil 210, a trace of the primary coil 210 can be accommodated between the two turns connected by the crossing structure 222a (i.e., the first turn 200_1 and the third turn 200_3). Specifically, the outermost turn of the primary coil 210 (i.e., the second turn 200_2 of the integrated transformer 200) can be accommodated. For comparison, the two turns connected by the crossing structure 212a (i.e., the fourth turn 200_4 and the fifth turn 200_5) do not accommodate any other turn of the integrated transformer 200.

Reference is made to FIG. 2 and FIG. 3B. The crossing structure 212a is a portion of the primary coil 210 (i.e., the current entering the secondary coil 220 from the terminal 224a or terminal 224b will not flow through the crossing structure 212a) and connects the fourth turn 200_4 and the fifth turn 200_5 of the integrated transformer 200. The fourth turn 200_4 and the fifth turn 200_5 are two consecutive turns of the integrated transformer 200.

Approximately three-fourths of the sixth turn 200_6 of the integrated transformer 200 belongs to the primary coil 210 (i.e., being a portion of the primary coil 210), while approximately one-fourth of the sixth turn 200_6 (i.e., approximately the trace 221g) belongs to the secondary coil 220 (i.e., being a portion of the secondary coil 220).

Approximately one-fourth of the fifth turn 200_5 of the integrated transformer 200 belongs to the primary coil 210, while approximately three-fourths of the fifth turn 200_5 belongs to the secondary coil 220.

The fourth turn 200_4, the fifth turn 200_5, and the sixth turn 200_6 are three consecutive turns of the integrated transformer 200.

The two turns connected by the crossing structure 202a and the crossing structure 202b (i.e., the fifth turn 200_5 and the sixth turn 200_6) do not belong to a single coil. More specifically, the fifth turn 200_5 (or the sixth turn 200_6) is distributed across the primary coil 210 and the secondary coil 220. In other words, a portion of the fifth turn 200_5 (or the sixth turn 200_6) belongs to the primary coil 210, and another portion of the fifth turn 200_5 (or the sixth turn 200_6) belongs to the secondary coil 220.

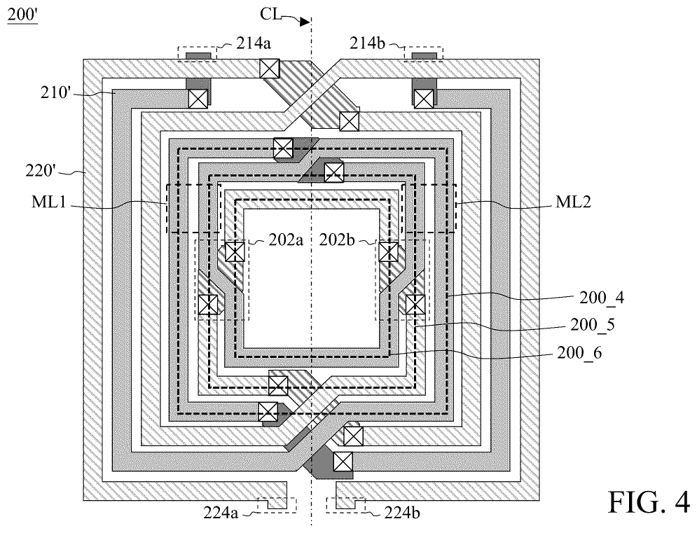

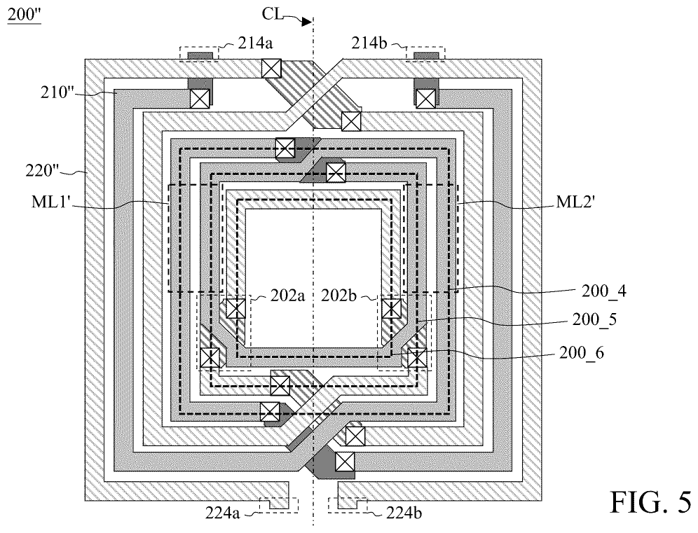

The positions of the crossing structure 202a and the crossing structure 202b are among the factors affecting the ratio of the inductance value of the primary coil 210 to the inductance value of the secondary coil 220. The following provides further explanation in connection with FIG. 4 and FIG. 5.

Reference is made to FIG. 4, which shows the structure of the integrated transformer according to another embodiment of the present invention. The integrated transformer 200′ is similar to the integrated transformer 200, except that the positions of the crossing structure 202a and the crossing structure 202b have been changed. More specifically, compared to the integrated transformer 200 in FIG. 2, the crossing structure 202a and the crossing structure 202b of the integrated transformer 200′ are closer to the terminal 224a and the terminal 224b. This results in a greater mutual inductance between the fourth turn 200_4 and the fifth turn 200_5 of the primary coil 210′ (as shown in the mutual inductance region ML1 and the mutual inductance region ML2), which increases the inductance value of the primary coil 210′.

In addition, approximately half of the sixth turn 200_6 of the integrated transformer 200′ belongs to the primary coil 210′, and approximately the other half of the sixth turn 200_6 belongs to the secondary coil 220′. Similarly, approximately half of the fifth turn 200_5 of the integrated transformer 200′ belongs to the primary coil 210′, and approximately the other half of the fifth turn 200_5 belongs to the secondary coil 220′.

Reference is made to FIG. 5, which shows the structure of the integrated transformer according to another embodiment of the present invention. The integrated transformer 200″ is similar to the integrated transformer 200′, except that the positions of the crossing structure 202a and the crossing structure 202b have been changed. More specifically, compared to the integrated transformer 200′ in FIG. 4, the crossing structure 202a and the crossing structure 202b of the integrated transformer 200″ are closer to the terminal 224a and the terminal 224b. This results in a greater mutual inductance between the fourth turn 200_4 and the fifth turn 200_5 of the primary coil 210″ (as shown in the mutual inductance region ML1′ and the mutual inductance region ML2′), which increases the inductance value of the primary coil 210″.

In addition, approximately one-fourth of the sixth turn 200_6 of the integrated transformer 200″ belongs to the primary coil 210″, and approximately three-fourths of the sixth turn 200_6 belongs to the secondary coil 220″. Similarly, approximately three-fourths of the fifth turn 200_5 of the integrated transformer 200″ belongs to the primary coil 210″, and approximately one-fourth of the fifth turn 200_5 belongs to the secondary coil 220″.

For the same integrated transformer, when more parts (i.e., a larger proportion) of the coil are distributed in the inner turns of the integrated transformer, the inductance value of the coil is smaller. Therefore (please refer to FIG. 2 and FIG. 5), the inductance value of the primary coil 210″ of the integrated transformer 200″ is larger than the inductance value of the primary coil 210 of the integrated transformer 200, because the proportion of the primary coil 210″ in the sixth turn 200_6 (the innermost turn) of the integrated transformer 200″ is smaller (about one-fourth), while the proportion in the fifth turn 200_5 is larger (about three-fourths). For the same reason, the inductance value of the secondary coil 220″ of the integrated transformer 200″ is smaller than the inductance value of the secondary coil 220 of the integrated transformer 200.

In summary, the integrated transformer of the present invention has the following advantages: (1) The ratio of the inductance values between the primary coil and the secondary coil can be adjusted by changing the positions of the crossing structure 202a and the crossing structure 202b; and (2) only two conductor layers are needed.

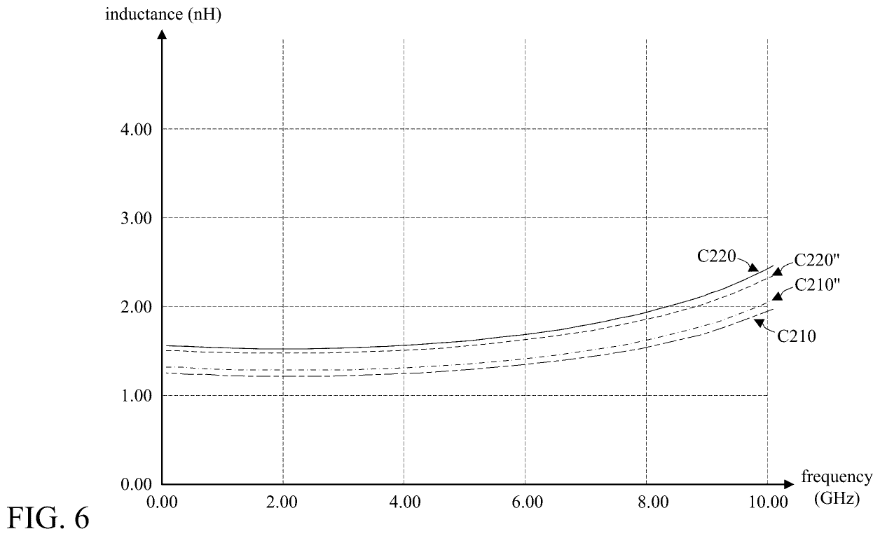

Reference is made to FIG. 6, which shows the relationship between the inductance value and the frequency of the integrated transformer according to the present invention. The curves C210, C220, C210″, and C220″ respectively represent the inductance values of the primary coil 210, the secondary coil 220, the primary coil 210″, and the secondary coil 220″. It can be seen from the figure that after fine-tuning (by changing the positions of the crossing structure 202a and the crossing structure 202b), the inductance value of the primary coil 210″ (1.362 nH) is greater than the inductance value of the primary coil 210 (1.297 nH), while the inductance value of the secondary coil 220″ (1.564 nH) is less than the inductance value of the secondary coil 220 (1.622 nH).

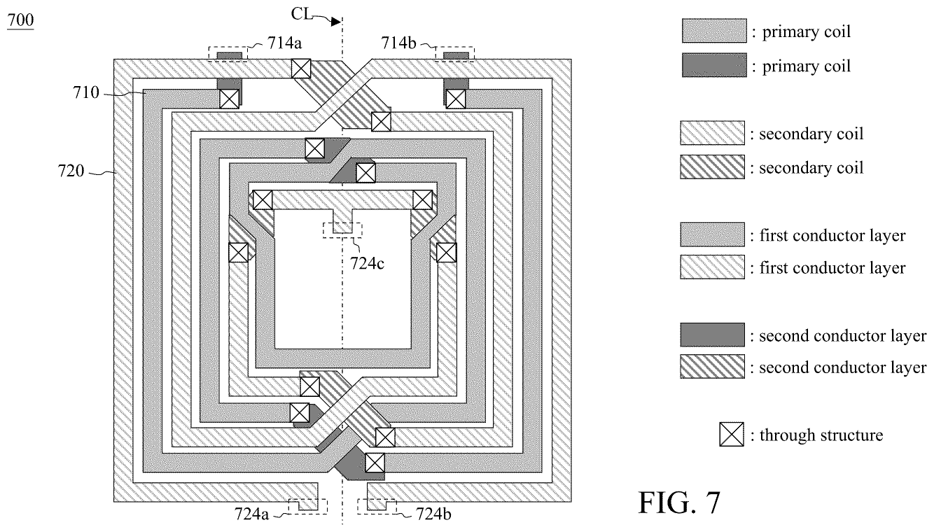

Reference is made to FIG. 7, which shows the structure of a balun according to an embodiment of the present invention. The balun 700 includes a primary coil 710 and a secondary coil 720. The terminal 714a and the terminal 714b are two terminals of the primary coil 710, while the terminal 724a, the terminal 724b, and the terminal 724c are three terminals of the secondary coil 720. The terminal 724c is on the axis of symmetry CL. The balun 700, the primary coil 710, and the secondary coil 720 are all symmetrical with respect to the axis of symmetry CL. The structure of the balun 700 is similar to that of the integrated transformer 200, with the primary coil 710 and the secondary coil 720 corresponding to the primary coil 210 and the secondary coil 220, respectively. People having ordinary skill in the art can understand the characteristics of the balun 700 based on the aforementioned discussion about the integrated transformer 200.

The two terminals 714a and 714b of the primary coil 710 can serve as the unbalanced terminals of the balun 700, while the three terminals 724a, 724b, and 724c of the secondary coil 720 can serve as the balanced terminals of the balun 700. As the operating principle of the balun is well known to people having ordinary skill in the art, further elaboration is omitted for brevity.

The pair of crossing structures (202a and 202b) is intended to illustrate the invention by way of example and not to limit the scope of the claimed invention. People having ordinary skill in the art may implement more pairs of crossing structures on an integrated transformer or a balun in accordance with the foregoing discussions.

The number of turns in the aforementioned embodiments (6 turns) is intended to illustrate the invention by way of example and not to limit the scope of the claimed invention. People having ordinary skill in the art may implement the integrated transformer or the balun with more or fewer turns in accordance with the foregoing discussions.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An integrated transformer having a first terminal, a second terminal, a third terminal, and a fourth terminal, the integrated transformer comprising:
a primary coil including a first trace, wherein the first terminal and the second terminal are two terminals of the primary coil;
a secondary coil including a second trace and a third trace, wherein the third terminal and the fourth terminal are two terminals of the secondary coil;
a first crossing structure formed by the second trace and a first portion of the first trace; and
a second crossing structure formed by the third trace and a second portion of the first trace;
wherein the integrated transformer is substantially symmetrical with respect to an axis of symmetry, the first terminal and the second terminal are located on two sides of the axis of symmetry, the third terminal and the fourth terminal are located on two sides of the axis of symmetry, and the first crossing structure and the second crossing structure are substantially symmetrical with respect to the axis of symmetry.

2. The integrated transformer of claim 1, wherein the primary coil further comprises a third crossing structure, the third crossing structure connects a first turn and a second turn of the integrated transformer, and the first turn and the second turn are two consecutive turns of the integrated transformer.

3. The integrated transformer of claim 2, wherein the third crossing structure is on the axis of symmetry.

4. The integrated transformer of claim 2, wherein the first crossing structure connects the second turn and a third turn of the integrated transformer, the second crossing structure connects the second turn and the third turn, and the second turn and the third turn are two consecutive turns of the integrated transformer.

5. The integrated transformer of claim 4, wherein the third turn is the innermost turn of the integrated transformer.

6. The integrated transformer of claim 1, wherein the integrated transformer comprises a first turn and a second turn, the first crossing structure connects the first turn and the second turn, the second crossing structure connects the first turn and the second turn, and positions of the first crossing structure and the second crossing structure determine a first proportion of the first turn occupied by the primary coil and a second proportion of the second turn occupied by the primary coil.

7. The integrated transformer of claim 6, wherein the first turn and the second turn are two consecutive turns of the integrated transformer.

8. The integrated transformer of claim 6, wherein the integrated transformer further comprises a third turn, the third turn, the first turn, and the second turn are three consecutive turns of the integrated transformer, the primary coil further comprises a third crossing structure, and the third crossing structure connects the first turn and the third turn.

9. The integrated transformer of claim 8, wherein the second turn is the innermost turn of the integrated transformer.

10. A balanced-to-unbalanced transformer (balun), having a first terminal, a second terminal, a third terminal, a fourth terminal, and a fifth terminal, the balun comprising:
a primary coil including a first trace, wherein the first terminal and the second terminal are two terminals of the primary coil;
a secondary coil including a second trace and a third trace, wherein the third terminal, the fourth terminal, and the fifth terminal are three terminals of the secondary coil;
a first crossing structure formed by the second trace and a first portion of the first trace; and
a second crossing structure formed by the third trace and a second portion of the first trace;
wherein the balun is substantially symmetrical with respect to an axis of symmetry, the first terminal and the second terminal are located on two sides of the axis of symmetry, the third terminal and the fourth terminal are located on two sides of the axis of symmetry, the fifth terminal is on the axis of symmetry, and the first crossing structure and the second crossing structure are substantially symmetrical with respect to the axis of symmetry.

11. The balun of claim 10, wherein the first terminal and the second terminal are unbalanced terminals of the balun, and the third terminal, the fourth terminal, and the fifth terminal are balanced terminals of the balun.

12. The balun of claim 11, wherein the primary coil further comprises a third crossing structure, the third crossing structure connects a first turn and a second turn of the balun, and the first turn and the second turn are two consecutive turns of the balun.

13. The balun of claim 12, wherein the third crossing structure is on the axis of symmetry.

14. The balun of claim 12, wherein the first crossing structure connects the second turn and a third turn of the balun, the second crossing structure connects the second turn and the third turn, and the second turn and the third turn are two consecutive turns of the balun.

15. The balun of claim 14, wherein the third turn is the innermost turn of the balun.

16. The balun of claim 11, wherein the balun comprises a first turn and a second turn, the first crossing structure connects the first turn and the second turn, the second crossing structure connects the first turn and the second turn, and positions of the first crossing structure and the second crossing structure determine a first proportion of the first turn occupied by the primary coil and a second proportion of the second turn occupied by the primary coil.

17. The balun of claim 16, wherein the first turn and the second turn are two consecutive turns of the balun.

18. The balun of claim 16, wherein the balun further comprises a third turn, the third turn, the first turn, and the second turn are three consecutive turns of the balun, the primary coil further comprises a third crossing structure, and the third crossing structure connects the first turn and the third turn.

19. The balun of claim 18, wherein the second turn is the innermost turn of the balun.
